(19) United States
(12) Patent Application Publication
(10) Pub. No.: US 2026/0229243 A1
(43) Pub. Date: Aug. 6, 2026

(54) Dialog Intelligibility Enhancement Method and System

(71) Applicant: DTS, Inc., Calabasas, CA (US)

(72) Inventors: Martin Walsh, Scotts Valley, CA (US); Fabio Di Marco, Galway (IE)

(73) Assignee: DTS, Inc., Calabasas, CA (US)

(21) Appl. No.: 19/149,729

(22) PCT Filed: Feb. 7, 2024
(86) PCT No.: PCT/US2024/014744

§ 371 Date: Jul. 21, 2025

Related U.S. Application Data
(60) Provisional application No. 63/483,737, filed on Feb. 7, 2023.
(60) Provisional application No. 63/508,811, filed on Jun. 16, 2023.

(51) Int. Cl. G10L 21/0364; G10L 21/034; G10L 25/78

(52) U.S. Cl. CPC G10L 21/0364; G10L 21/034; G10L 25/78

(57) ABSTRACT

Aspects of the present invention regard a method and system for enhancing dialogue intelligibility in an original audio signal that comprises dialogue components and non-dialogue components. The method comprises providing the dialogue components of the original audio signal in a first separate audio signal, providing the non-dialogue components of the original audio signal in a second separate audio signal, processing the first separate audio signal and the second separate audio signal separately, wherein processing the first and second separate audio signals comprises processing the loudness of the first separate audio signal and/or of the second separate audio signal, and combining the processed first and second separate audio signals to provide a processed audio signal.

### RELATED APPLICATION AND PRIORITY CLAIM

This application is related to and claims priority to U.S. Provisional Application No. 63/483,737, filed on Feb. 7, 2023, and entitled “DIALOG ENHANCEMENT ECOSYSTEM FOR STREAMING AND BROADCASTING MEDIA”, and is related to and claims priority to U.S. Provisional Application No. 63/508,811, filed on Jun. 16, 2023, and entitled “DIALOG ENHANCEMENT T ECOSYSTEM FOR STREAMING AND BROADCASTING MEDIA”, which are hereby incorporated by reference in their entirety.

### BACKGROUND

The present disclosure relates to enhancing dialogue intelligibility in an audio signal that comprises dialogue components and non-dialogue components. For example, audio soundtracks of video content that may be played back on a media device, such as a set top box, a TV, a laptop, etc. The mixed soundtrack may be composed of narrative dialogue and non-dialogue audio components. The non-dialogue components may include ambient or environmental sounds, music, and sound-effects, for example.

Often, the consumer cannot understand dialogue from the mixed soundtrack as it is played-back through a sound reproduction system in a consumer's playback environment. The consumer may not be able to understand the dialogue due to many factors that can degrade the intelligibility of the spoken word. This often forces the consumer to continually change the content volume level, turning down the volume if the music and effects are too loud and turning it back up when dialogue is too quiet. This can take them out of the content watching experience and causes frustration. In addition, simply turning up the device's master volume level will not solve issues with intelligibility, as this will increase the volume of both the dialogue and the interfering non-dialogue soundtrack.

Accordingly, there is a need to improve intelligibility of the dialogue components in an audio signal.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

An aspect of the invention provides for a method for enhancing dialogue intelligibility in an original audio signal that comprises dialogue components and non-dialogue components. The method comprises providing the dialogue components of the original audio signal in a first separate audio signal, providing the non-dialogue components of the original audio signal in a second separate audio signal, processing the first separate audio signal and the second separate audio signal separately, wherein processing the first and second separate audio signals comprises processing the loudness of the first separate audio signal and/or of the second separate audio signal, and combining the processed first and second separate audio signals to provide a processed audio signal.

Aspects of the invention are thus based on the idea to analyze and process the dialogue components and the non-dialogue components of an audio signal independently. This allows to process the dialogue components and the non-dialogue components individually, thereby providing for improved intelligibility of the dialogue components. In particular, the dialogue components may be adjusted or equalized differently than the non-dialogue components. For example, the dialogue components may receive loudness normalization and optionally spectral enhancement, while the non-dialogue components may receive a dynamic range compression, as will be discussed below.

Within the meaning of the present invention, dialogue components are components that regard spoken language (including intervals of silence between spoken words), wherein non-dialogue components regard the other components of an audio signal such as music and sound effects. Dialogue components may also be referred to as foreground speech, wherein non-dialogue components may also be referred to as background sounds.

It is pointed out that the method steps are not necessarily carried out by the same entity. For example, the step of providing the dialogue components of the original audio signal in a first separate audio signal and providing the non-dialogue components of the original audio signal in a second separate audio signal may be carried out in a head end system or cloud. The step of processing the first separate audio signal and the second separate audio signal separately and the step of combining the processed signals may be carried out on a consumer device. In another embodiment, the dialogue separation is carried out in a higher-powered device at a customer site such as a set-top box or television, while processing the first and second separate audio signals is provided for by another customer device such as a consumer device. In other embodiments, however, all steps are implemented in the same device such as a consumer device.

In an embodiment, providing the dialogue components in a first separate audio signal and providing the non-dialogue components in a second separate audio signal comprises receiving the first and second separate audio signals from a source in which the first and second separate audio signals are separately available. Accordingly, if separate dialogue-only and non-dialogue signals are already available from the production stage, they may be used directly. For example, a discrete dialogue stream may be available using object-based audio, such as DTS: X®, Dolby Atmos® or MPEG-H®.

In another embodiment, providing the dialogue components in a first separate audio signal and providing the non-dialogue components in a second separate audio signal comprises separating the dialogue components from the non-dialogue components in the original audio signal. Separating the dialogue components from the non-dialogue components may be implemented by a plurality of methods. For example, dialogue separation may be implemented by deep learning models like convolutional neural networks and recurrent neural networks which allow the ability to isolate different sources, including a dialogue. There exist commercially available products for dialogue separation based on neural networks such as RX Dialogue Isolate from iZotope, Inc. Another method relies on analyzing object-based audio as discussed in J. Paulus et al.: “Source Separation for Enabling Dialogue Enhancement in Object-Based Broadcast with MPEG-H”, J. Audio Eng. Soc., Vol. 67, No. 7/8, 2019 July/August.

In an embodiment, processing the first separate audio signal comprises determining a short-term loudness level of the first separate audio signal, and determining whether the determined short-term loudness level is less than a predefined minimum dialogue loudness level DLL_{MIN}. In cases where the determined short-term loudness level is less than the predefined minimum dialogue loudness level DLL_{MIN}, the first separate audio signal is amplified towards the predefined minimum dialogue loudness level DLL_{MIN}. If the determined short-term loudness level is not less than the minimum dialogue loudness level DLL_{MIN}, the first separate audio signal is not modified.

In this aspect of the invention, the parameter “minimum dialogue loudness level” (DLL_{MIN}) defines a target short term average loudness level for the dialogue components. If the measured dialogue level is less than the target DLL_{MIN}, the first separate audio signal (the dialogue signal) is amplified towards the target minimum level. It is pointed out that no signal modification is applied if the dialogue loudness is already above DLL_{MIN}. A typical default value of DLL_{MIN} would match industry recommendations for digital dialogue loudness levels. This generally ranges from between −22 LUFS to −27 LUFS. Since most program content will follow these recommendations, dialogue loudness may not need to be modified significantly to achieve this target.

In a further embodiment, the processed first separate audio signal is spectrally enhanced before combining it with the processed second separate audio signal. Such spectral enhancement is optional and may include the application of specific filters to the dialogue components.

In a still further embodiment, the method further comprises determining a voice activity in the first separate audio signal, and amplifying the first separate audio signal towards the minimum dialogue loudness level DLL_{MIN} only in case a voice activity has been determined. This embodiment is based on the idea that dialogue loudness should only be boosted if there is voice activity. Otherwise, extremely low-level dialogue components such as background dialogue or noise/artifacts in the dialogue signal would be subjected to undesirable high gains to match the DLL_{MIN} level. This can lead to undesired loudness spikes during transitions from quiet segments to those with narrative dialogue, as the normalization ballistics need time to adjust to rapid loudness changes.

One example of determining a voice activity comprises determining if the short-term loudness level of the first separate audio signal is higher than a threshold dialogue loudness level DLL_{THRESH}, wherein the first separate audio signal is amplified towards the minimum dialogue loudness level DLL_{MIN} only in case the determined short-term loudness level is higher than the threshold dialogue loudness level DLL_{THRESH}. In this embodiment, the parameter “threshold dialogue loudness level (DLL_{THRESH})” functions as a voice activity detector (VAD), below which dialogue loudness is not boosted. Additionally, DLL_{THRESH} helps to avoid amplifying low-level processing artifacts from a preceding dialogue separation process.

It is pointed out that this aspect of the invention is not limited to the specific implementation of VAD as a threshold parameter. It may also include other voice activity detection implementations, such as those using output masks from dialogue separation processes or machine learning algorithms designed for voice activity detection.

In an embodiment, amplifying the first separate audio signal comprises using a dynamic range processor that applies a gain by using a modifiable curve determined by a number of control points. Such modifiable curve may be determined by 5 control points (x/y coordinates) and allows the processor to function as a compressor, expander, loudness leveler, or a hybrid of these modes. A smoothing parameter may also be incorporated to ensure seamless transitions between operational zones.

In an embodiment, processing the second separate audio signal comprises determining a short-term loudness level of the first separate audio signal or obtaining a predefined minimum dialogue loudness level DLL_{MIN} of the first separate audio signal, determining a short-term loudness level of the second separate audio signal, and determining whether the difference between the short-term loudness level of the first separate audio signal and the short-term loudness level of the second separate audio signal or the difference between the minimum dialogue loudness level DLL_{MIN} and the short-term loudness level of the second separate audio signal is less than a predefined minimum dialogue to non-dialogue ratio D2ND_{MIN}. If so, the loudness level of the second separate audio signal is decreased such that said difference approaches the minimum dialogue to non-dialogue ratio D2ND_{MIN}. If not so, the second separate audio signal is not modified.

In this embodiment, the parameter “Minimum Dialogue-to-non-dialogue Ratio (D2ND_{MIN}) represents the minimum difference between the short-term dialogue and the short-term non-dialogue loudness levels. If the measured levels have a loudness difference that is less than this value, the non-dialogue signal is compressed until the average difference between the dialogue loudness level and non-dialogue loudness levels approaches D2ND_{MIN}. It is pointed out that the non-dialogue levels are only decreased when necessary.

In an embodiment, decreasing the loudness level of the second separate audio signal comprises compressing the dynamic range of the second separate audio signal. This may be implemented by using a dynamic range processor that applies a gain by using a modifiable curve determined by a number of control points, the control points allowing the processor to function as a compressor and/or loudness leveler. For example, if the mentioned difference is below the D2ND_{MIN} value, a specific compression ratio such as 2:1 may be implemented such that the difference approaches the D2ND_{MIN} value.

In a still further embodiment, a short-term loudness level (of the first separate audio signal that includes the dialogue components or of the second separate audio signal that includes the non-dialogue components) is determined for consecutive windows of predefined length, wherein the loudness level is determined in accordance with an industry standard. The windows may lie in the range between 10 ms and 100 ms. For example, the windows have a length of 20 ms. The industry standard according to which the loudness level is determined may be the ITU-R BS.1770 standard, wherein loudness is denoted in LKFS (Loudness, K-weighted, relative to Full Scale) or its synonymous term LUFS (Loudness units relative to full scale) introduced in EBU R128, which is a standard loudness measurement unit used for audio normalization in broadcast television systems and other video and music streaming services. In particular, the first iteration of this standard, ITU-R BS.1770-1, may be used to determine a loudness as this standard is particularly suited to handle immediate loudness fluctuations through continuous short-term measurement.

In a further embodiment, the first separate audio signal and the second separate audio signal are processed in a plurality of processing paths, the processing paths including a general processing path, wherein the processed audio signal is provided to any number of listeners, and at least one individualized processing path, wherein the processed audio signal is provided to an individual listener, wherein processing the first separate audio signal and/or processing the second separate audio signal comprises using parameters personalized to the individual listener during the processing. The personalized parameters may include a listener-specific personal hearing profile and subjective listening preferences. This embodiment addresses the situation that not everyone in the listening space wishes to hear a common audio output from a dialogue enhancement system. Therefore, alternative degrees of dialogue processing may be implemented according to the needs of one or several.

In an embodiment, the original audio signal is an audio soundtrack, i.e., a sound accompanying and synchronized to the images of a motion picture, TV program, videogame, radio program, etc. The original soundtrack may be in the form of a digital audio file. However, the present invention is not limited to such embodiment. For example, the original audio signal may be a live audio signal.

In a further embodiment, the original audio signal is a stereo signal or multichannel signal. It may be provided that for each channel of the stereo signal or multichannel signal the dialogue components are provided in a first separate audio signal and the non-dialogue components are provided in a second separate audio signal, wherein the first and second separate audio signals are processed separately and combined afterwards. Accordingly, in this embodiment, the number of channels at the input is maintained at the output.

In a further embodiment, the original audio signal is a stereo signal, wherein the stereo signal is upmixed to a 3-channel signal comprising a center channel, a left channel and a right channel, wherein the signal components of the stereo signal originally panned to the center are extracted to the center channel. It is further provided that only for the center channel the dialogue components are provided in a first separate audio signal and the non-dialogue components are provided in a second separate audio signal. The first separate audio signal and the second separate audio signal are processed in accordance with the invention, wherein the second separate audio channel is combined with the left and right channels for loudness processing. This embodiment requires channel dialogue separation for a single channel only, thereby reducing complexity.

In a further embodiment, the original audio signal is a multichannel signal comprising a center channel and a plurality of further channels, wherein only for the center channel the dialogue components are provided in a first separate audio signal and the non-dialogue components are provided in a second separate audio signal, as it is assumed that dialogue is most prevalent in the center channel. The first separate audio signal and the second separate audio signal are processed in accordance with the invention, wherein the second separate audio channel is combined with the further channels for loudness processing. This embodiment requires channel dialogue separation for a single channel only in a multichannel signal, thereby reducing complexity.

In a further embodiment, the original audio signal is a multichannel signal comprising a center channel, a left channel, a right channel and further channels, wherein the center channel, the left channel and the right channel are downmixed to two channels, wherein for each of the downmixed two channels the dialogue components are provided in a first separate audio signal and the non-dialogue components are provided in a second separate audio signal. This embodiment assumes that the majority of dialogue is present in the front (center, left, right) channels. The first separate audio signal and the second separate audio signal are processed in accordance with the invention, wherein the second separate audio signals are combined with the further channels for loudness processing. This embodiment requires channel dialogue separation for a single channel only in a multichannel signal, thereby reducing complexity.

In a further embodiment, the processed first separate audio signal and the processed second separate audio signal are further processed by applying spatial audio processing and/or specific algorithms before the processed first and second separate audio signals are combined. This embodiment is based on the realization that the first separate audio signal with the dialogue components and the second separate audio signal with the non-dialogue components may be kept separated for further downstream processing before being combined. For example, further processing may comprise the application of algorithms that include spatial audio processing for headphones and speakers. Other examples of downstream processing include algorithms that are better applied to only the non-dialogue components of the input signal, such as bass enhancement.

According to a further aspect of the invention, a method for enhancing dialogue in an original audio signal that comprises dialogue components and non-dialogue components is provided for. The method comprises receiving the dialogue components of an original audio signal in a first separate audio signal, receiving the non-dialogue components of the original audio signal in a second separate audio signal, and processing the first separate audio signal and the second separate audio signal separately, wherein processing the first and second separate audio signals comprises processing the loudness of the first separate audio signal and/or of the second separate audio signal.

This aspect of the invention focuses on the separate processing of the first separate audio signal and the second separate audio signal. The method may be implemented at a consumer site in a consumer device such as a television, laptop, smart phone, or headphones.

According to a further aspect of the invention, a system for enhancing dialogue in an original audio signal that comprises dialogue components and non-dialogue components is provided for. The system comprises a dialogue separation unit that is configured to provide the dialogue components of the original audio signal in a first separate audio signal and to provide the non-dialogue components of the original audio signal in a second separate audio signal. The system further comprises a loudness processing unit configured to process the first separate audio signal and the second separate audio signal separately, wherein processing the first and second separate audio signals comprises processing the loudness of the first separate audio signal and/or of the second separate audio signal. There is further provided an audio mixer configured to combine the processed first and second separate audio signals to provide a processed audio signal.

It is pointed out that the dialogue separation unit, the loudness processing unit and the audio mixer are not necessarily included in the same entity. For example, the dialogue separation unit may be implemented in a head end or cloud. The loudness processing unit and the audio mixer may be implemented on a consumer device. In another embodiment, dialogue separation unit is implemented in a higher-powered device at a customer site such as a set-top box or television, while the loudness processing unit and the audio mixer are implemented in another customer device such as a consumer device.

Embodiments of the system correspond to embodiments of the method discussed above. For example, the dialogue separation unit may be configured to receive the dialogue components and the non-dialogue components from a source in which the first and second separate audio signals are separately available. Alternatively, the dialogue separation unit may be configured to provide the dialogue components and the non-dialogue components by separating the dialogue components from the non-dialogue components in the original audio signal.

According to a still further aspect of the invention, a non-transitory computer-readable medium having executable instructions stored thereon is provided for, wherein, when the instructions are executed by a processor, the operations are performed: providing the dialogue components of an original audio signal in a first separate audio signal, providing the non-dialogue components of the original audio signal in a second separate audio signal, processing the first separate audio signal and the second separate audio signal separately, wherein processing the first and second separate audio signals comprises processing the loudness of the first separate audio signal and/or of the second separate audio signal, and combining the processed first and second separate audio signals to provide a processed audio signal.

Embodiments of the non-transitory computer-readable medium correspond to embodiments of the method discussed above.

### BRIEF DESCRIPTION OF THE DRAWINGS

Throughout the drawings, reference numbers are re-used to indicate correspondence between referenced elements. The drawings are provided to illustrate embodiments of the inventions described herein and not to limit the scope thereof.

FIG. 1 is a general system architecture of a system for enhancing dialogue in an original audio signal, wherein the system architecture comprises a dialogue separation unit, a loudness processing unit and an audio mixing unit;

FIG. 2 shows an embodiment of the dialogue separation unit of FIG. 1;

FIG. 3 is a flowchart of a method for enhancing dialogue in an original audio signal;

FIG. 4 is a flowchart of a method for processing a first separate audio signal that comprises dialogue components of an original audio signal;

FIG. 5 is a flowchart of a method for processing a second separate audio signal that comprises non-dialogue components of the original audio signal;

FIG. 6 is an embodiment of the loudness processing unit of FIG. 1;

FIG. 7 is an embodiment of a dynamic range processor;

FIG. 8 illustrates loudness measurement of a multichannel audio signal in accordance with ITU-R BS.1770-1;

FIG. 9 is an example of a dialogue loudness modification curve;

FIG. 10 is an example of non-dialogue loudness modification curve;

FIG. 11 is a flowchart of an example method for processing a first separate audio signal that comprises dialogue components of an original audio signal;

FIG. 12 is a flowchart of an example method for processing a second separate audio signal that comprises non-dialogue components of the original audio signal;

FIG. 13 illustrates a system implementing centralized dialogue separation with distributed personalized dialogue enhancement;

FIG. 14 illustrates a further system implementing centralized dialogue separation with distributed personalized dialogue enhancement, wherein 2-channel wireless transmission and endpoint-specific postprocessing is provided;

FIG. 15 is a stereo in/out implementation of the general system of FIG. 1;

FIG. 16 is a further stereo implementation of the general system of FIG. 1, wherein separated dialogue channels are retained for additional post processing;

FIG. 17 is a further stereo implementation of the general system of FIG. 1, wherein a single channel dialogue separation is implemented;

FIG. 18 shows an embodiment of a stereo shuffler;

FIG. 19 is a further stereo implementation of the general system of FIG. 1, wherein a single channel dialogue separation is implemented using a stereo shuffler;

FIG. 20 is a multichannel implementation of the general system of FIG. 1, wherein a single channel dialogue separation is implemented;

FIG. 21 is a further multichannel implementation of the general system of FIG. 1, wherein a stereo dialogue separation is implemented; and

FIG. 22 is a further multichannel implementation of the general system of FIG. 1, wherein a 3-channel dialogue separation is implemented.

### DETAILED DESCRIPTION

The following description describes various embodiments of methods and systems that enhance a dialogue in an original audio signal that comprises dialogue components and non-dialogue components.

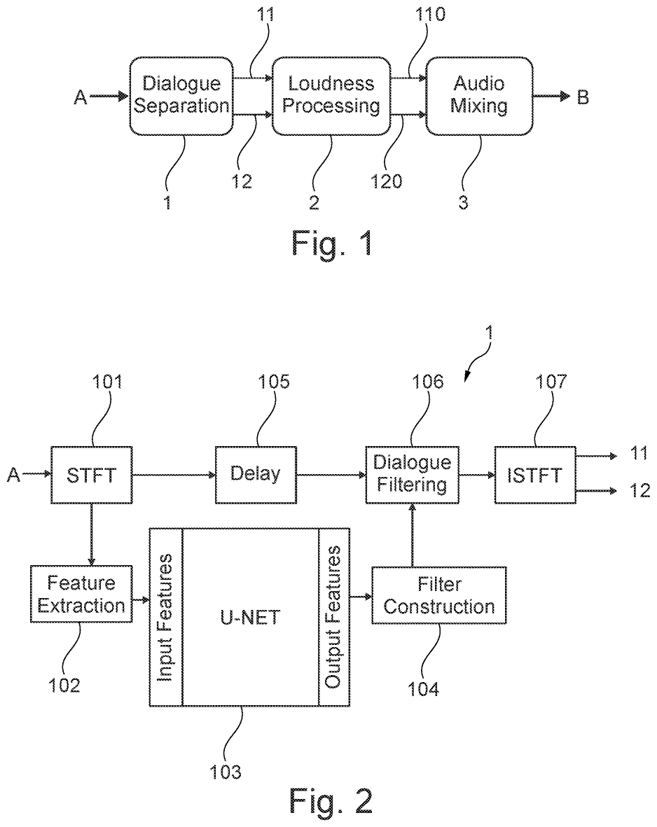

FIG. 1 shows the general system architecture. The system comprises a dialogue separation unit 1, a loudness processing unit 2 and an audio mixing unit 3. The dialogue separation unit 1 receives an original audio signal A and separates the dialogue components from the other components of the signal. The dialogue components are provided in a first separate audio signal 11 and the non-dialogue components are provided in a second separate audio signal 12. Once the dialogue components are separated, they can be analyzed and processed separately from the non-dialogue components. The dialogue components include spoken language. The non-dialogue components represent any signal component that is not a narrative dialogue signal. They may include music and sound effects.

The original audio signal A may be a digital audio signal. It may be stored in a file or be streamed. For example, the original audio signal is an audio soundtrack of video content that may be played back on a media device such as a set top box, a TV, a laptop, etc. In another example, the original audio signal is a live radio transmission.

The loudness processing unit 2 receives the first separate audio signal 11 that comprises the dialogue components and the second separate audio signal 12 that comprises the non-dialogue components and processes first separate audio signal 11 and the second separate audio signal 12 separately. In particular, the audio signals 11, 12 are analyzed and processed for loudness separately as will be discussed in embodiments with respect to FIGS. 4, 5, 11 and 12. The loudness processing unit 2 serves to ensure that the dialogue loudness level is never lower than the listener's desired level and also adapts the non-dialogue loudness level such that there is a consistent minimum dialogue-to-non-dialogue ratio. The audio mixer 3 receives the processed first separate audio signal 110 and the processed second separate audio signal 120 and combines them to provide as output a processed audio signal B that is dialogue enhanced. For example, a dialogue enhanced soundtrack is output audio mixer 3.

It is pointed out that the system components 1, 2, 3 may be split between devices. For example, the dialogue separation unit 1 may occur at the head end or in the cloud and the dialogue processing unit 21 may occur on a consumer device. In another example, one higher powered device (e.g., a set top box or TV) includes the dialogue separation unit 1 while another device may include the dialogue processing unit 2 and the audio mixer 3.

FIG. 2 shows an example embodiment of the dialogue separation unit 1 of FIG. 1. The purpose of the dialogue separation unit 1 is to separate the incoming original audio signal A into two separate signals 11, 12 having dialogue components and non-dialogue components, respectively. In the depicted embodiment, but not necessarily, a machine learning network is trained to perform this task. However, other audio source separation techniques could also be used.

According to the embodiment of FIG. 2, the original audio mix is converted to the short time Fourier transform (STFT) domain in an STFT unit 101 and pertinent audio features are extracted from the STFT data in a feature extraction unit 102. For example, the data could be converted to a log magnitude representation and the linear frequency bands may be grouped into a smaller number of critical perceptual bands. The input features are taken as the input layer of a machine learning network 103 (e.g., one based on the U-NET architecture) and targets a set of output features. The output features in this case represent a set of frequency domain weights that represent the filtering required to isolate dialogue and/or non-dialogue signal components. The output features are processed such that a linear STFT domain representation can be derived. These per-frequency-bin weights are applied to a delayed version (delayed by a delay unit 105) of the original STFT-domain signals in a dialogue filtering unit 106. The delay is used to compensate for the processing latency involved in the feature extraction, network inference and reconstruction. The resulting filtered STFT data is then converted back to the time domain using inverse STFT processing in an ISTFT unit 107. The extracted dialogue components are output in the first separate audio signal 11 and the non-dialogue components are output in the second separate audio signal 12.

The machine learning network may have been trained by a large database of separated dialogue and non-dialogue signal examples (which represent the desired output) and their corresponding mixtures (provided at the input).

In case the first and second separate audio signals 11, 12 are readily available from a source such as a production stage source, there is no need for dialogue separation such that the dialogue separation unit 2 may then be bypassed or be reduced to a unit that simply receives the first and second separate audio signals 11, 12.

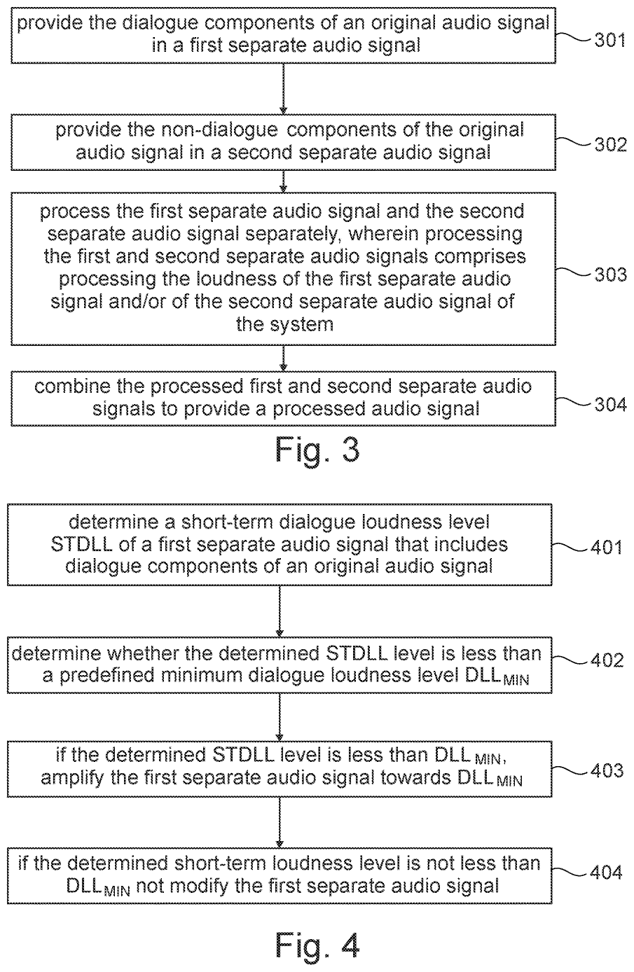

FIG. 3 is a flowchart of a method for enhancing dialogue in an original audio signal. In the steps 301 and 302, the dialogue components and the non-dialogue components of an original audio signal are provided in first and second separate audio signals. The dialogue components and the non-dialogue components may be provided for by dialogue separation techniques such as discussed with respect to FIG. 2 or may be simply received if available separately. In step 303, the first separate audio signal and the second separate audio signal are processed separately, wherein the loudness of the first separate audio signal and/or of the second separate audio signal to improve dialogue intelligibility. This may be implemented in the loudness processing unit 2 of FIG. 1, a more specific embodiment of which is discussed with respect to FIG. 6. In step 304, the processed first and second separate audio signals are combined to provide a processed audio signal.

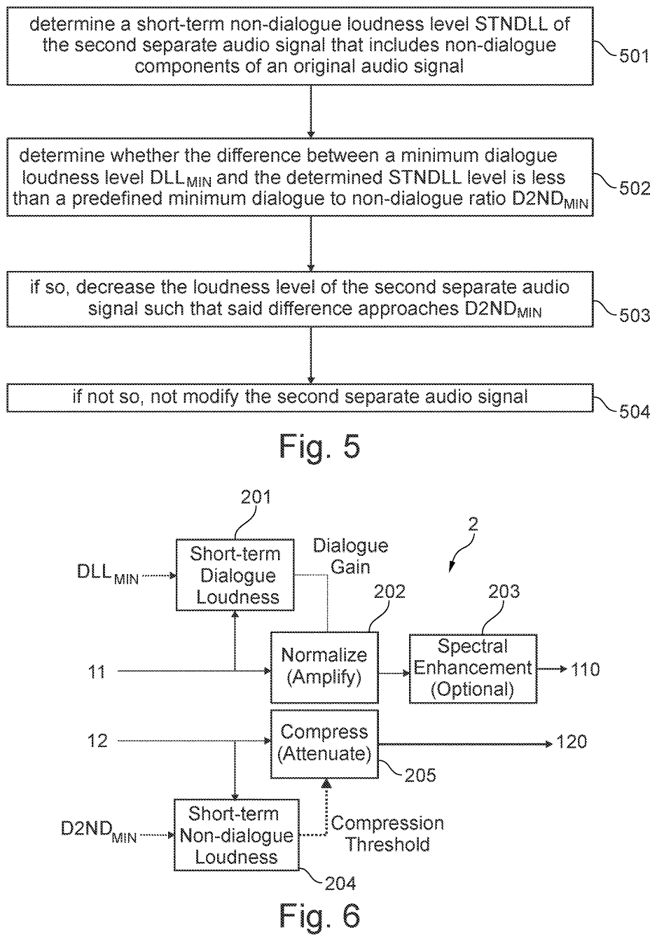

Examples of how the first and second separate audio signals are processed are provided in FIGS. 4 and 5. According to FIG. 4, in a first step 401 a short-term dialogue loudness level (STDLL) of the first separate audio signal is determined. Such loudness level determination may be based on standard loudness measurements as will be discussed below. The measurement of a short-term loudness implies that the loudness is measured on a window. For example, short-term loudness is measured on a small window of 20 ms with a look-ahead of 10 ms to have the window centered around the current samples, while this is to be understood as an example only and other window lengths and look-aheads may be implemented.

In step 402, it is determined whether the determined STDLL is less than a predefined minimum dialogue loudness level (DLL_{MIN}). If this is the case, the first separate audio signal is amplified in step 403 towards DLL_{MIN}. If not, the first separate audio signal is not modified. Accordingly, the loudness of the first separate audio signal with the dialogue input is normalized to the predefined minimum dialogue loudness level DLL_{MIN}.

It is to be noted that a such approach substantially differs from prior art approaches. Prior art approaches implement volume normalization to ensure that the level of quiet passages is increased to a more audible level, and dynamic range compression to ensure that the level of overly loud passages is reduced. However, when applied to an original soundtrack mix the combination of these processes can create audible artifacts. For example, with volume normalization enabled, quiet non-dialogue passages (e.g. a non-dialogue forest treescape) will become unnaturally loud. Similarly, the use of dynamic range compression on louder nondialogue soundtrack components may also affect louder dialogue, making it even harder to hear it in the presence of non-dialogue sounds. Additionally, these solutions often apply a high frequency spectral boost to the signal to increase dialogue clarity. This filter is usually applied to the non-dialogue components as well as the dialogue components of the mix, affecting the overall spectral balance of the soundtrack.

On the other hand, when first separating the dialogue components and the non-dialogue components into two separate signals, the short-term loudness of the separated dialogue components can be analyzed independently from the non-dialogue components. This allows to apply loudness normalization to the dialogue signals only.

FIG. 5 is an example of how the second separate audio signal comprising the non-dialogue components may be processed. In step 501 a short-term non-dialogue loudness level (STNDLL) of the second separate audio signals that include the non-dialogue components is determined. Again, this is implemented by windowing the second separate audio signal. Similar as with the processing of the first separate audio signal, a short-term loudness may be measured on a small window of 20 ms with a look-ahead of 10 ms. Generally, the window size for determining the short-term loudness of the first separate audio signal may or may not be the same as the window size for determining the short-term loudness of the second separate audio signal. In this respect, it is to be noted that the technique of applying different processing to the dialogue and non dialogue streams is associated with the further advantage that different loudness windows may be applied for each stream.

In step 502, it is determined whether the difference between a minimum dialogue loudness level DLL_{MIN} (the same DLL_{MIN} level that has been discussed with respect to FIG. 3) and the STNDLL level determined in step 501 is less than a predefined minimum dialogue to non-dialogue ratio D2ND_{MIN}. If so, the loudness level of the second separate audio signal is decreased such that said difference approaches the ration D2ND_{MIN}, step 503. If not so, the second separate audio signal is not modified, step 504. Decreasing the loudness level of the second separate audio signal may be implemented by compressing the dynamic range of the second separate audio signal.

A decrease of the loudness level is effected for the non-dialogue signals only.

Alternatively, instead of determining the difference between the minimum dialogue loudness level DLL_{MIN} and the STNDLL level, the difference between the short-term loudness level (STDLL) of the first separate audio signal and the STNDLL level is determined and analyzed to be less than the predefined minimum dialogue to non-dialogue ratio D2ND_{MIN} or not.

FIG. 6 shows an embodiment of the loudness processing unit 2 of FIG. 1. The loudness processing unit 2 comprises a unit 201 for determining the short-term loudness of the first separate audio signal 11. The unit 201 receives as input parameter the predefined minimum dialogue loudness level DLL_{MIN} discussed with respect to FIG. 4. The loudness processing unit 2 further comprises an amplifying unit 202 configured to amplify the first separate audio signal 11 in accordance with control signals received by unit 201. Further, optionally, a spectral enhancement unit 203 for the first separate audio signal 11 is provided. Regarding the second separate audio signal 12, a unit 204 for determining the short-term loudness of the second separate audio signal 12 is provided. The unit 204 receives as input parameter the predefined minimum dialogue to non-dialogue ratio D2ND_{MIN} discussed with respect to FIG. 5. The loudness processing unit 2 further comprises a compression unit 205 configured to compress the second separate audio signal 12 in accordance with control signals provided by unit 204. The loudness processing unit 2 outputs a processed first separate audio signal 110 and a processed second separate audio signal 120.

The parameters DLL_{MIN} and D2ND_{MIN} may be set by a consumer or a system integrator.

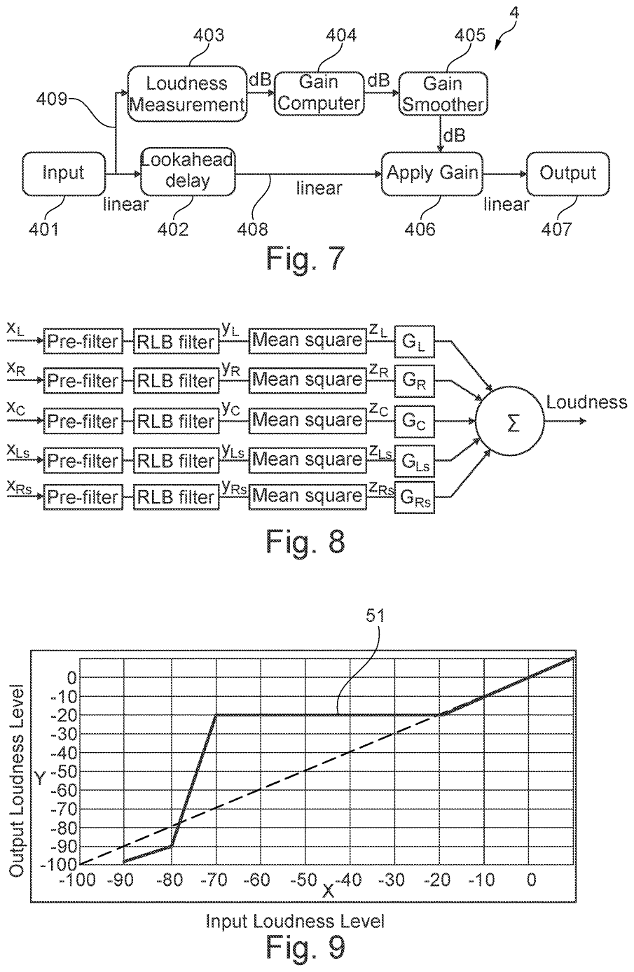

Units 201, 202 and 204, 205 may be implemented using a versatile Dynamic Range Processor (DRP) as depicted in FIG. 7. The DSP can be adapted for handling both dialogue and non-dialogue input streams. The signal received at an input 401 is duplicated and delayed in a lookahead delay unit 402 in a first path 408. For example, a lookahead delay of 10 ms is incorporated to prepare the DRP to proactively respond to incoming loudness transients. In a second path 409, a loudness measurement unit 403, a gain computer 404 and a gain smoother 405 are provided. The determined gain is applied in unit 406 to the signal in path 408 and send to an output 407.

In the loudness measurement unit 403, the loudness of the signal is measured. In particular, the short-term loudness of the first separate audio signal 11 or the short term loudness of the second separate audio signal 12 may be measured. Loudness measurement is carried out in accordance with an industry standard. In an embodiment, loudness is estimated using the industry-standard ITU-R BS.1770-1 and measured with a specific window size auch as 20 ms to ensure both precision and responsiveness. In standard ITU-R BS. 1770 loudness is denoted in LKFS (Loudness, K-weighted, relative to Full Scale) or its synonymous term LUFS (Loudness units relative to full scale) introduced in EBU R128, which is a standard loudness measurement unit used for audio normalization in broadcast television systems and other video and music streaming services. In particular, the first iteration of this standard, ITU-R BS.1770-1 which is particularly suited to handle immediate loudness fluctuations through continuous short-term measurement may be used.

The ITU-R BS.1770-1 standard processes each audio channel by initially applying a pair of second order IIR filters pre-filtering and RLB (Revised Low-Frequency B-curve) filtering to emulate the human ear's frequency response. Subsequently, the mean-square energy of the filtered signal over a measurement interval T is calculated, yielding the value zi for each channel i. The mean-square energy is determined as follows:

$${z}_{i} = \frac{1}{T} {\int }_{0}^{T} {y}_{\dot{t}}^{2} ( t ) dt$$

Post mean-square calculation, channel-specific weightings Gi are applied, culminating in the aggregate loudness value:

$$Loudness = - 0.691 + 10 {log}_{10} ( {\sum }_{i} {G}_{i} \cdot {z}_{i} )$$

Channel weightings may be assigned as follows: Left (GL): 1.0; Right (GR): 1.0; Centre (Gc): 1.0; Left surround (GLs): 1.41; Right surround (GRs): 1.41. The procedure is illustrated in FIG. 8.

Referring again to FIG. 7, the gain computer 404 computes the gain using a modifiable curve determined by five control points (x/y coordinates). This allows the processor to function as a Compressor, Expander, Loudness Leveler, or a hybrid of these modes. A smoothing parameter may also be incorporated in gain smoother 405 to ensure seamless transitions between operational zones. The gain smoother may be a branching attack and release smoother, with settings for fast/slow attack and release times that enable the processor to quickly adapt to significant changes in input loudness.

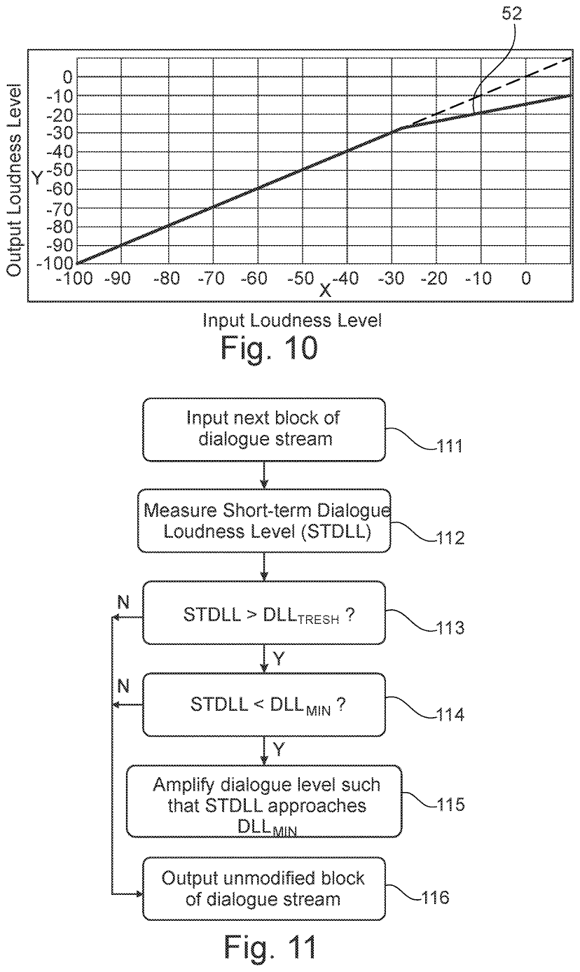

FIGS. 9 and 10 show an example of a dialogue loudness modification curve 51 and of a non-dialogue loudness modification curve 52. As mentioned, the gain is computed using a modifiable curve determined by five control points, which provides the flexibility to use it for both dialogue (upward gain) and non-dialogue (attenuation) processing. Example curves for dialogue and non-dialogue are demonstrated in FIGS. 9 and 10. In these examples, the following parameter values are used: DLL_{MIN}=−20dBFS; D2ND_{MIN}=10 dB; and DLL_{TRESH}=−80 dB. In practice, these curves are smoothed to ensure seamless transitions between operational zones.

The parameters DLL_{MIN} and D2ND_{MIN} have been discussed before. The parameter DLL_{TRESH} defines a Threshold Dialogue Loudness Level. This parameter functions as a voice activity detector (VAD) below which dialogue loudness is not boosted. Without DLL_{TRESH}, extremely low-level dialogue components (e.g. background dialogue or noise/artifacts on the dialogue channel) would be subjected to undesirable high gains to match DLL_{MIN}. This can lead to undesired loudness spikes during transitions from quiet segments to those with narrative dialogue, as the normalization ballistics need time to adjust to rapid loudness changes. Additionally, DLL_{THRESH} helps avoid amplifying low-level processing artifacts from the preceding dialogue separation process.

In FIG. 9, the dialogue loudness modification curve 51 is made of four loudness operational zones. In a first zone from −inf dB to −80 dB the loudness is attenuated by 10 dB. In the given example, −80 dB is the Threshold Dialogue Loudness Level DLL_{TRESH}. As stated before, below the DLL_{TRESH} level the dialogue loudness is not boosted. In the present example, it is even attenuated by 10 dB. In a second zone from −80 dB to −70 dB there is a gradual transition from a compression zone to a normalization zone. The third zone from −70 dB to −20 dB is the zone in which the loudness is normalized to the DLL_{MIN} value. In the fourth zone from −20 dB to +inf dB the signal is left unchanged.

In FIG. 10, the non-dialogue loudness modification curve 52 is made of two loudness operational zones. In a first zone from −inf dB to −30 dB the signal is left unchanged. In a second zone from −30 dB to +inf dB the signal is compressed, wherein the compression ratio is 2:1. The compression ratio may be different in other embodiments.

FIG. 11 indicates the method implemented by loudness processing unit 2 of FIG. 6 with respect to processing of the first separate audio signal that comprises the dialogue components. The method is based on the method of FIG. 4 but comprises additional details. In step 111, a block of dialogue stream is input, wherein the block size is defined by a window. The window size may be 20 ms in embodiments. In step 112, the short-term loudness level STDLL of the dialogue components is measured, such as discussed with respect to FIGS. 7 and 8. In step 113, it is determined if the short-term loudness level STDLL is larger than a predefined Threshold Dialogue Loudness Level DLL_{TRESH}. If not, an unmodified block of dialogue stream is output in step 116. If so, it is further determined in step 114 if the short-term loudness level STDLL is smaller than a predefined minimum dialogue loudness level DLL_{MIN} which is set in accordance with industry recommendations and may lie in the range between −22 LUFS to −27 LUFS (LUFS=“Loudness Units Full Scale”). If not, an unmodified block of dialogue stream is output in step 116. If so, the level of the dialogue components is amplified in step 115 such that the short-term loudness level STDLL approaches or is equal to the minimum dialogue loudness level DLL_{MIN}, as indicated in the third zone of FIG. 9. The sequence of steps 113, 114 may be reversed.

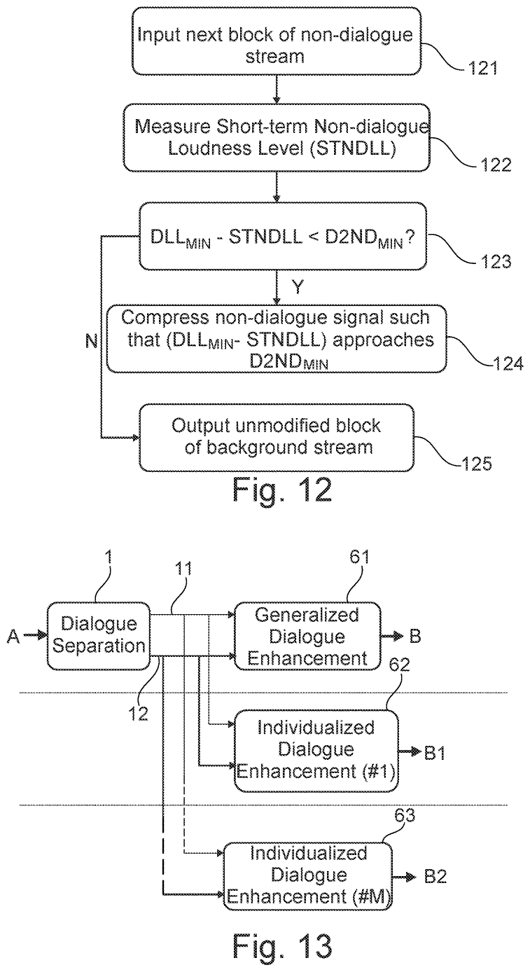

FIG. 12 indicates the method implemented by loudness processing unit 2 of FIG. 6 with respect to processing of the second separate audio signal that comprises the non-dialogue components. The method is based on the method of FIG. 5 but comprises additional details. In step 121, a block of non-dialogue stream is input, wherein the block size is defined by a window. The window size may be 20 ms in embodiments. In step 122, the short-term loudness level STNDLL of the non-dialogue components is measured, such as discussed with respect to FIGS. 7 and 8. In step 123, it is determined if the difference between the minimum dialogue loudness level DLL_{MIN} and the short-term loudness level STNDLL measured in step 122 is less than a predefined minimum dialogue to non-dialogue ratio D2ND_{MIN}. If this is not the case, an unmodified block of non-dialogue stream is output in step 125. If this is the case, the non-dialogue signal is compressed such that the mentioned difference DLL_{MIN}-STNDLL approaches the minimum dialogue to non-dialogue ratio D2ND_{MIN}. Compression may include dynamic range compression. An example is given in FIG. 10.

In the above embodiments, it is assumed that everyone in a listening space will hear a common audio output from the dialogue enhancement system. In this case, the algorithm applies dialogue processing according to the preference of a single listener and will be heard by all those in the listening environment. FIG. 13 shows an alternative system in which alternative degrees of dialogue processing can be provided to individual listeners according to their needs (for example, individuals with more pronounced hearing loss).

More particularly, in FIG. 13, an original audio signal A is split into dialogue and non-dialogue components in a dialogue separation unit as discussed with respect to FIG. 1. Alternatively, if the dialogue and non-dialogue components are already available separately, they are simply received. Subsequently, the first and second audio signals 11, 12 are provided to a series of processing paths. A first processing path is a general processing path, wherein the processed audio signal B is provided to any number of listeners listening to the same processed mix (e.g., over TV speakers). The separated signals 11, 12 are processed in a generalized dialogue enhancement unit 61 which corresponds to the loudness processing unit 2 and the audio mixing unit 3 of FIG. 1.

Further, one or multiple optional individualized processing paths are provided, wherein an individualized audio output B1, B2 is provided for in that when processing the first separate audio signal 11 and/or processing the second separate audio signal 12 personalized parameters of the individual listener are considered. For example, a listener specific personal hearing profile or subjective listening preferences may be implemented in an individualized dialogue enhancement unit 62, 63 and applied to the individual processing blocks. The individualized audio output B1, B2 may be replayed over headphones or hearing assisted devices.

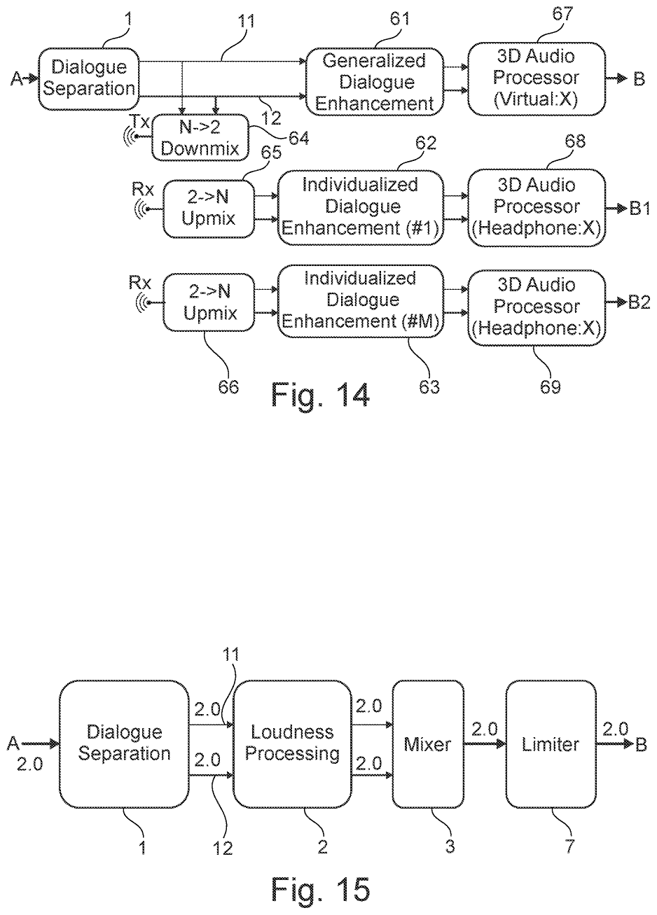

Individualized mixes can be directed to in-ear monitors or headphones using a wired connection or using a low latency wireless technology such as Bluetooth or ultra-wideband audio (UWB), as shown in FIG. 14. In FIG. 14, if the number of channels of the audio input A is larger than two, the channels are downmixed to stereo in an downmix unit 64 and the downmixed channels are wirelessly transmitted to upmixing units 65, 66 associated with individual users. After upmixing, and individualized dialogue enhancement is implemented in units 62, 63. The output of the dialogue enhancement units 61, 62, 63 may be further improved by a 3D audio processor 67, 68, 69 that may be embedded with or attached to headphones used by the individual listener.

In this respect, a plurality of variations may be implemented. In one embodiment, an individual listener hearing device may include a noise cancellation feature to minimize interference from the generalized version of the soundtrack played over loudspeakers. Multiple individualized mixes can be generated at a hub (e.g. TV or set-top box) and transmitted simultaneously from that source. Further, in some embodiments, multichannel audio output content may be downmixed to stereo before transmission. In some embodiments, multichannel individual audio output content may be sent to a multichannel headphone virtualization technology, such as DTS Headphone: X before wireless transmission. Such virtualization algorithm may be applied on the transmitting device or in the headphones. In some embodiments, the unmixed dialogue and non-dialogue audio streams are transmitted wirelessly to one or more headset sets which have the necessary processing capabilities, and the individualized dialogue processing is applied in the headphones. In some embodiments, the dialogue and non-dialogue audio streams are downmixed or encoded (spatially or otherwise) in a way that allows a lower bandwidth transmission and receiving of the original audio channels. For example, a stereo downmix of the original dialogue and background channels can be done such that the dialogue is center-panned and a multichannel non-dialogue signal is spatially encoded to stereo using an algorithm such as the DTS Neural Surround downmixer. This stereo signal can then be ‘upmixed’ or decoding back to discrete dialogue and non-dialogue streams on the receiving headphone device. In some embodiments, the original input signal is transmitted wirelessly to a headphone which has onboard processing capabilities, including a machine learning inference engine. The original audio soundtrack is transmitted to the headphones and the dialogue separation, and the individualized dialogue processing are applied on a processor attached to or embedded within the headphones.

Different implementation topologies of the system and method will be discussed with respect to FIGS. 15 to 22 in the following.

In FIG. 15, the input audio signal A is a stereo signal (indicated as “2.0”). Separation into a first separate audio stereo signal 11 for the dialogue components and a second separate audio stereo signal 12 for the non-dialogue components is implemented by a dialogue separation unit 1 that has been trained to separate dialogue and non-dialogue components from a stereo signal. The separated stereo dialogue and non-dialogue components are then passed to a stereo loudness processing unit 2 and the processed components are once again mixed. Additionally, an output limiter 7 may be provided for to ensure that the processed signal does not saturate downstream.

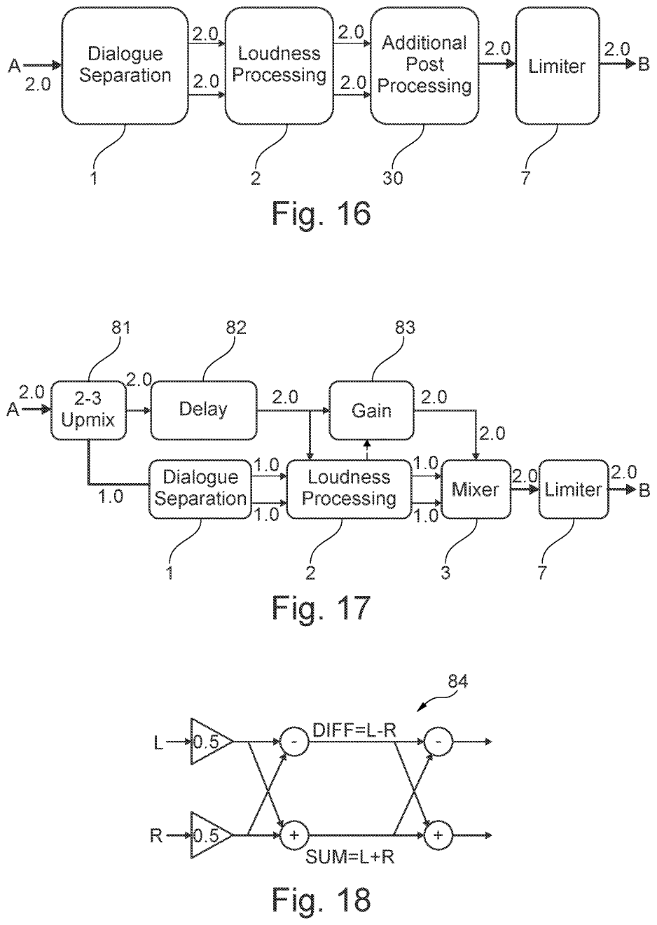

In the embodiment of FIG. 16, the input audio signal A is a stereo signal. The outputs of the loudness processing unit 2 are kept separated for further downstream processing in an additional post processing unit 30, into which the audio mixing unit is integrated. The postprocessing unit 30 may include algorithms for spatial audio processing for headphones and speakers. Other examples of downstream processing include algorithms that are better applied to only the non-dialogue components of the input signal, such as bass enhancement. The basic concept of retaining the separated dialogue and non-dialogue outputs from the loudness processing unit 2 can be applied to any of the topologies described below. As in FIG. 15, in addition an output limiter 7 is provided.

In the embodiment of FIG. 17, the input audio signal A is also a stereo signal. However, dialogue separation is provided for a single channel only. It is assumed that the majority of the narrative content dialogue is center panned. More particularly, a stereo input A with L, R channels is upmixed to 3-channels (L,C,R) in unit 81 such that signal components originally panned to center are extracted to a discrete center channel C. The resulting signals now take two separate paths. The C component is directed to the single channel dialogue separation unit 1. Since it is assumed that the primary dialogue is represented in the extracted center channel, it can be assumed that the residual (L,R) channels represent non-dialogue components. These residual channels are delayed in delayer 82, compensating for the dialogue separation processing delay, and redirected to the loudness processing unit 2 (as they are considered when processing the non-dialogue signal components in loudness processing unit 2). The loudness processing unit 2 evaluates the relative loudness of the separated dialogue and the loudness of the residual C and (L,R) non-dialogue components, and applies gains and attenuations to each signal component wherein the accordingly, (L,R) channels are amplified/compressed in amplifier/compressor unit 83. The signals are then downmixed in audio mixer 3 to a single stereo pair and, in this case, directed to an output limiter 7. In the embodiment of FIG. 17, the loudness processing unit 2 comprises multiple inputs. A first input is the extracted dialogue channel. One or several further inputs are the extracted non-dialogue channels. Further, it is assumed that the L, R channels from the upmix unit 81 contain non-dialogue only.

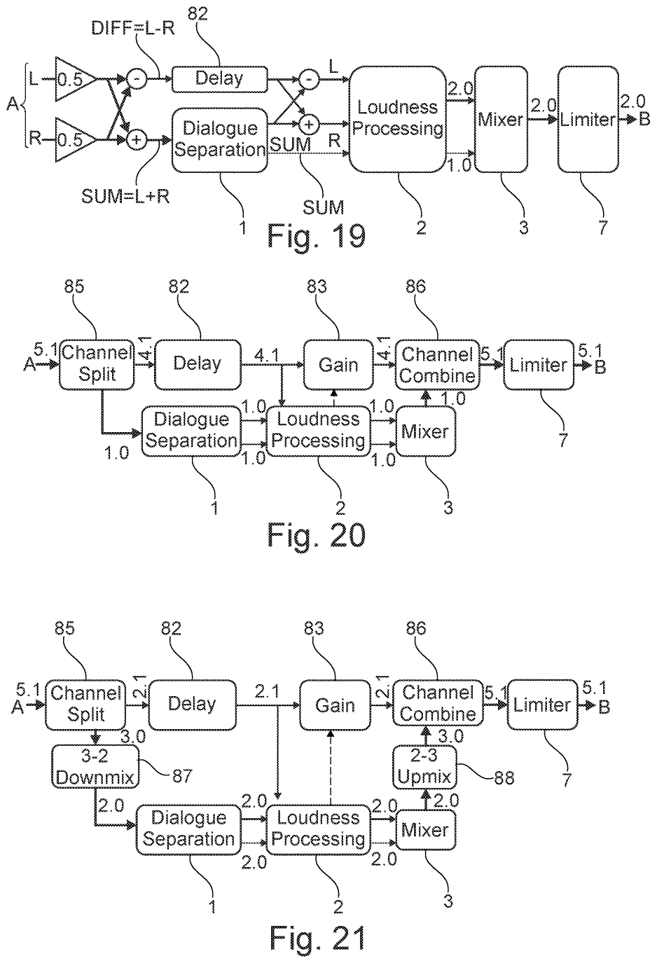

FIGS. 18 and 19 regard an alternative embodiment of a system in which the input audio signal A is a stereo signal, wherein dialogue separation and loudness processing is provided for a single channel only. This embodiment regards the situation in which an active 2-3 upmixer is not available to the implementor. In such case, it is possible to apply a passive upmix using a stereo shuffler configuration. A typical stereo shuffler configuration 84 is shown in FIG. 18. Sums and differences of right and left input channel L and R are formed twice for each channel. The outputs are the same as the inputs for a typical stereo shuffler.

With the basic assumption that narrative dialogue is generally center-panned, the sum L+R of the stereo input channels will contain a large proportion of that center panned signal component and the difference L-R of the input channels will contain little or no dialogue. Therefore, most of the dialogue can be extracted from the sum component L+R, as shown in FIG. 19, and the sum component receives dialogue separation and dialogue separation unit 1. The stereo non-dialogue signal is then synthesized using the original difference signal L-R and the non-dialogue component of the original sum signal L+R. The recreated stereo non-dialogue signal components and the mono sum signal are then analyzed by the loudness processing unit 2 and then remixed in audio mixer 3 to an augmented stereo signal. As with other examples, the resulting output signal is directed to an output limiter 7.

In the embodiment of FIG. 20, the input audio signal A is a multichannel signal (5.1 in the depicted embodiment). It is assumed that dialogue is already most prevalent in the center channel of the multichannel audio stream. Conversely, it is assumed that all other channels can be non-dialogue. Therefore, the center channel is simply redirected to a single channel (1.0) dialogue separation processor 1 and the loudness processing unit 2 considers the relative loudness of the separated dialogue to the residual non-dialogue channels (including the residual from the center channel). The loudness processing the appropriate gains and delays to each signal component and each signal is recombined to match the input multichannel format (5.1 in this embodiment). A multichannel limiter 7 is finally applied to the resulting 5.1 channel output.

In the embodiment of FIG. 21, the dialogue separation model has been trained to separate dialogue and dialogue components from a stereo signal, as show in FIG. 15. In this case, it can be assumed that the majority of dialogue will be present in the front (L,C,R) channel mixes. After a channel split in unit 85, these channels are downmixed in downmixer 87 to a stereo signal and directed to the stereo dialogue separation unit 1. The other channels (2.1: LS,RS, LFE) are assumed to contain no narrative dialogue in this case. The loudness of the separated stereo dialogue is compared in the loudness processing unit 2 to the loudness of the residual stereo non-dialogue channels along with the (LS, RS, LFE) channels. Appropriate gains are calculated and applied to all channel signal components. The separated dialogue and non-dialogue outputs, originally derived from (L,C,R), are mixed together in audio mixer 3 and further up-mixed to their original 3-channel layout using a 2-3 channel upmixer 88 and the resulting signals are once again combined in a channel combiner 86 with the original surround and LFE channel components and reconstructed to match the original input format. As before, a multichannel limiter may finally be applied to the resulting 5.1 channel output.

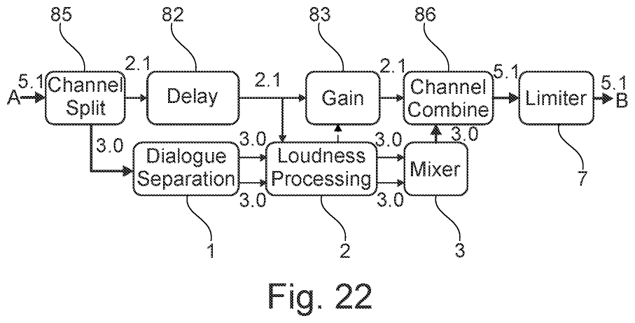

In the embodiment of FIG. 22, a dialogue separation unit 1 is used that has been trained on a three-channel input signal. As a result, there is no need to downmix or upmix the (L,C,R) channels.

The above described embodiments and implementation topologies may receive a plurality of adaptions.

In some embodiments, the individualized processed audio output, or part thereof, is directed at specific individuals using a beamforming loudspeaker array.

In some embodiments, the wireless receiver may be a hearing assistance device (hearing aid). In this case, care must be taken to ensure that the dialogue processing preferences are chosen with the inbuilt hearing assistance technology accounted for.

In some embodiments, the general audio output can also be broadcast to multiple wireless receivers, with no loudspeaker output. This would minimize acoustic crosstalk for all listeners.

In some embodiments, only the dialogue channel is used for individualized processing and wireless transmission. This may be the case if a listener only needs reinforcement of the dialogue signal. This may be done using bone conducting headphones, nearfield speakers, or open ear headphones.

In some embodiments, the system might use imaging sensors that can identify listener(s) presence and position. This may affect the algorithm parameters to use. For example, the preferences of a particular person may only be used if that person is in the room. Alternatively, a weighted average of parameters for everyone detected in the room may be used. Listener position may be useful when considering environmental noise or if beamforming dialogue to a specific individual.

In some embodiments, different user preferences may be applied for different types of content. For example, one might prefer a different set of loudness processing parameters for drama than for news. Content type may be gotten from content metadata or it may be determined using algorithmic classification.

In some embodiments, where the described processing is applied in a self-contained wearable device (e.g. hearables, augmented reality headset) it might be used in environments outside of the home (e.g. cinema or theater). By default, the loudness adaptation algorithm is based on digital loudness levels (relative to digital full scale). Some amount of SPL to digital level calibration must be made to ensure a degree of equivalent when only microphone captures of acoustic signals are available.

In some embodiments, the automated closed captioning may be displayed on the augmented reality displays or glasses.

### Alternate Embodiments and Exemplary Operating Environment

Many other variations than those described herein will be apparent from this document. For example, depending on the embodiment, certain acts, events, or functions of any of the methods and algorithms described herein can be performed in a different sequence, can be added, merged, or left out altogether such that not all described acts or events are necessary for the practice of the methods and algorithms. Moreover, in certain embodiments, acts or events can be performed concurrently, such as through multi-threaded processing, interrupt processing, or multiple processors or processor cores or on other parallel architectures, rather than sequentially. In addition, different tasks or processes can be performed by different machines and computing systems that can function together.

The various illustrative logical blocks, modules, methods, and algorithm processes and sequences described in connection with the embodiments disclosed herein can be implemented as electronic hardware, computer software, or combinations of both. To clearly illustrate this interchangeability of hardware and software, various illustrative components, blocks, modules, and process actions have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of this document.

The various illustrative logical blocks and modules described in connection with the embodiments disclosed herein can be implemented or performed by a machine, such as a general purpose processor, a processing device, a computing device having one or more processing devices, a digital signal processor DSP, an application specific integrated circuit ASIC, a field programmable gate array FPGA or other programmable logic device, discrete gate or transistor logic, discrete hardware components, or any combination thereof designed to perform the functions described herein. A general purpose processor and processing device can be a microprocessor, but in the alternative, the processor can be a controller, microcontroller, or state machine, combinations of the same, or the like. A processor can also be implemented as a combination of computing devices, such as a combination of a DSP and a microprocessor, a plurality of microprocessors, one or more microprocessors in conjunction with a DSP core, or any other such configuration.

Embodiments of the system and method described herein are operational within numerous types of general purpose or special purpose computing system environments or configurations. In general, a computing environment can include any type of computer system, including, but not limited to, a computer system based on one or more microprocessors, a mainframe computer, a digital signal processor, a portable computing device, a personal organizer, a device controller, a computational engine within an appliance, a mobile phone, a desktop computer, a mobile computer, a tablet computer, a smartphone, and appliances with an embedded computer, to name a few.

Such computing devices can typically be found in devices having at least some minimum computational capability, including, but not limited to, personal computers, server computers, hand-held computing devices, laptop or mobile computers, communications devices such as cell phones and PDA's, multiprocessor systems, microprocessor-based systems, set top boxes, programmable consumer electronics, network PCs, minicomputers, mainframe computers, audio or video media players, and so forth. In some embodiments the computing devices will include one or more processors. Each processor may be a specialized microprocessor, such as a digital signal processor DSP, a very long instruction word VLIW, or other micro-controller, or can be conventional central processing units CPUs having one or more processing cores, including specialized graphics processing unit GPU-based cores in a multi-core CPU.

The process actions or operations of a method, process, or algorithm described in connection with the embodiments disclosed herein can be embodied directly in hardware, in a software module executed by a processor, or in any combination of the two. The software module can be contained in computer-readable media that can be accessed by a computing device. The computer-readable media includes both volatile and nonvolatile media that is either removable, non-removable, or some combination thereof. The computer-readable media is used to store information such as computer-readable or computer-executable instructions, data structures, program modules, or other data. By way of example, and not limitation, computer readable media may comprise computer storage media and communication media.

Computer storage media includes, but is not limited to, computer or machine readable media or storage devices such as Bluray discs BD, digital versatile discs DVDs, compact discs CDs, floppy disks, tape drives, hard drives, optical drives, solid state memory devices, RAM memory, ROM memory, EPROM memory, EEPROM memory, flash memory or other memory technology, magnetic cassettes, magnetic tapes, magnetic disk storage, or other magnetic storage devices, or any other device which can be used to store the desired information and which can be accessed by one or more computing devices.

A software module can reside in the RAM memory, flash memory, ROM memory, EPROM memory, EEPROM memory, registers, hard disk, a removable disk, a CD-ROM, or any other form of non-transitory computer-readable storage medium, media, or physical computer storage known in the art. An exemplary storage medium can be coupled to the processor such that the processor can read information from, and write information to, the storage medium. In the alternative, the storage medium can be integral to the processor. The processor and the storage medium can reside in an application specific integrated circuit ASIC. The ASIC can reside in a user terminal. Alternatively, the processor and the storage medium can reside as discrete components in a user terminal.

The phrase “non-transitory” as used in this document means “enduring or long-lived”. The phrase “non-transitory computer-readable media” includes any and all computer-readable media, with the sole exception of a transitory, propagating signal. This includes, by way of example and not limitation, non-transitory computer-readable media such as register memory, processor cache and random-access memory RAM.

The phrase “audio signal” is a signal that is representative of a physical sound.

Retention of information such as computer-readable or computer-executable instructions, data structures, program modules, and so forth, can also be accomplished by using a variety of the communication media to encode one or more modulated data signals, electromagnetic waves such as carrier waves, or other transport mechanisms or communications protocols, and includes any wired or wireless information delivery mechanism. In general, these communication media refer to a signal that has one or more of its characteristics set or changed in such a manner as to encode information or instructions in the signal. For example, communication media includes wired media such as a wired network or direct-wired connection carrying one or more modulated data signals, and wireless media such as acoustic, radio frequency RF, infrared, laser, and other wireless media for transmitting, receiving, or both, one or more modulated data signals or electromagnetic waves. Combinations of the any of the above should also be included within the scope of communication media.

Further, one or any combination of software, programs, computer program products that embody some or all of the various embodiments of the system and method described herein, or portions thereof, may be stored, received, transmitted, or read from any desired combination of computer or machine readable media or storage devices and communication media in the form of computer executable instructions or other data structures.

Embodiments of the system and method described herein may be further described in the general context of computer-executable instructions, such as program modules, being executed by a computing device. Generally, program modules include routines, programs, objects, components, data structures, and so forth, which perform particular tasks or implement particular abstract data types. The embodiments described herein may also be practiced in distributed computing environments where tasks are performed by one or more remote processing devices, or within a cloud of one or more devices, that are linked through one or more communications networks. In a distributed computing environment, program modules may be located in both local and remote computer storage media including media storage devices. Still further, the aforementioned instructions may be implemented, in part or in whole, as hardware logic circuits, which may or may not include a processor.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense and not in its exclusive sense so that when used, for example, to connect a list of elements, the term “or” means one, some, or all of the elements in the list.

While the above detailed description has shown, described, and pointed out novel features as applied to various embodiments, it will be understood that various omissions, substitutions, and changes in the form and details of the devices or algorithms illustrated can be made without departing from the scope of the disclosure. As will be recognized, certain embodiments of the inventions described herein can be embodied within a form that does not provide all of the features and benefits set forth herein, as some features can be used or practiced separately from others.

1. A method for enhancing dialogue intelligibility in an original audio signal that comprises dialogue components and non-dialogue components, the method comprising:
providing the dialogue components of the original audio signal in a first separate audio signal;
providing the non-dialogue components of the original audio signal in a second separate audio signal;
processing the first separate audio signal and the second separate audio signal separately, wherein processing the first and second separate audio signals comprises processing the loudness of the first separate audio signal and/or of the second separate audio signal, and
combining the processed first and second separate audio signals to provide a processed audio signal.

2-12. (canceled)

13. The method of claim 1, wherein the first separate audio signal and the second separate audio signal are processed in a plurality of processing paths, the processing paths including
a general processing path, wherein the processed audio signal is provided to any number of listeners;
at least one individualized processing path, wherein the processed audio signal is provided to an individual listener, wherein processing the first separate audio signal and/or processing the second separate audio signal comprises using parameters personalized to the individual listener during the processing.

14. (canceled)

15. The method of claim 1, wherein the original audio signal comprises one or more of: is an audio soundtrack,
a stereo signal or multichannel signal, wherein for each channel of the stereo signal or multichannel signal the dialogue components are provided in a first separate audio signal and the non-dialogue components are provided in a second separate audio signal,
a stereo signal, wherein the stereo signal is upmixed to a 3-channel signal comprising a center channel, a left channel and a right channel, wherein the signal components of the stereo signal originally panned to the center are extracted to the center channel, and wherein only for the center channel the dialogue components are provided in a first separate audio signal and the non-dialogue components are provided in a second separate audio signal, and wherein the second separate audio channel is combined with the left and right channels for loudness processing
a multichannel signal comprising a center channel and a plurality of further channels, wherein only for the center channel the dialogue components are provided in a first separate audio signal and the non-dialogue components are provided in a second separate audio signal, and wherein the second separate audio signal is combined with the further channels for loudness processing, or
a multichannel signal comprising a center channel, a left channel, a right channel and further channels, wherein the center channel, the left channel and the right channel are downmixed to two channels, wherein for each of the downmixed two channels the dialogue components are provided in a first separate audio signal and the non-dialogue components are provided in a second separate audio signal, and wherein the second separate audio signals are combined with the further channels for loudness processing.

16-21. (canceled)

22. A system for enhancing dialogue intelligibility in an original audio signal that comprises dialogue components and non-dialogue components, the system comprising:
a dialogue separation unit configured to provide the dialogue components of the original audio signal in a first separate audio signal and to provide the non-dialogue components of the original audio signal in a second separate audio signal;
a loudness processing unit configured to process the first separate audio signal and the second separate audio signal separately, wherein processing the first and second separate audio signals comprises processing the loudness of the first separate audio signal and/or of the second separate audio signal, and
an audio mixer configured to combine the processed first and second separate audio signals to provide a processed audio signal.

23-24. (canceled)

25. The system of claim 22, wherein the loudness processing unit is configured to process the first separate audio signal by:
determining a short-term loudness level of the first separate audio signal;
determining whether the determined short-term loudness level is less than a predefined minimum dialogue loudness level DLL_{MIN},
if the determined short-term loudness level is less than the minimum dialogue loudness level DLL_{MIN}, amplify the first separate audio signal towards the predefined minimum dialogue loudness level DLL_{MIN},
if the determined short-term loudness level is not less than the minimum dialogue loudness level DLL_{MIN}, not modify the first separate audio signal.

26. The system of claim 25, wherein the loudness processing unit is further configured to spectrally enhance the processed first separate audio signal before combining it with the processed second separate audio signal.

27. The system of claim 25, wherein the loudness processing unit is further configured to:
determine a voice activity in the first separate audio signal;
amplify the first separate audio signal towards the minimum dialogue loudness level DLL_{MIN} only in case a voice activity has been determined.

28. The system of claim 27, wherein the loudness processing unit is configured to determine a voice activity by determining if the short-term loudness level of the first separate audio signal is higher than a threshold dialogue loudness level DLL_{THRESH}, wherein the first separate audio signal is amplified towards the minimum dialogue loudness level DLL_{MIN} only in case the determined short-term loudness level is higher than the threshold dialogue loudness level DLL_{THRESH}.

29. The system of claim 25, wherein the loudness processing unit comprises a dynamic range processor configured to amplify the first separate audio signal by applying a gain, wherein for applying the gain the dynamic range processor is configured to use a modifiable curve determined by a number of control points.

30. The system of claim 22, wherein the loudness processing unit is configured to process the second separate audio signal by:
determining a short-term loudness level of the first separate audio signal or obtaining a predefined minimum dialogue loudness level DLL_{MIN} of the first separate audio signal;
determining a short-term loudness level of the second separate audio signal;
determining whether the difference between the short-term loudness level of the first separate audio signal and the short-term loudness level of the second separate audio signal or the difference between the minimum dialogue loudness level DLL_{MIN} and the short-term loudness level of the second separate audio signal is less than a predefined minimum dialogue to non-dialogue ratio D2ND_{MIN};
if so, decreasing the loudness level of the second separate audio signal such that said difference approaches the minimum dialogue to non-dialogue ratio D2ND_{MIN},
if not so, not modify the second separate audio signal.

31. The system of claim 30, wherein the loudness processing unit is configured to decrease the loudness level of the second separate audio signal by compressing the dynamic range of the second separate audio signal.

32-33. (canceled)

34. The system of claim 22, wherein the first separate audio signal and the second separate audio signal are processed in a plurality of processing paths, the processing paths including
a general processing path comprising a general loudness processing unit, wherein the processed audio signal is provided to any number of listeners;
at least one individualized processing path comprising an individualized loudness processing unit, wherein the processed audio signal is provided to an individual listener, wherein processing the first separate audio signal and/or processing the second separate audio signal comprises using parameters personalized to the individual listener during the processing.

35. The system of claim 34, wherein the individualized loudness processing unit is configured to process the first and/or second separate audio signals using personalized parameters that include at least one of a listener-specific personal hearing profile and subjective listening preferences.

36. The system of claim 22, wherein the original audio signal is comprises at least one of:
an audio soundtrack,
a stereo signal or multichannel signal, wherein the dialogue separation unit is configured to provide for each channel of the stereo signal or multichannel signal the dialogue components in a first separate audio signal and the non-dialogue components in a second separate audio signal,
a stereo signal, wherein the system further comprises an upmixer configured to upmix the stereo signal to a 3-channel signal comprising a center channel, a left channel and a right channel, wherein the signal components of the stereo signal originally panned to the center are extracted to the center channel, and wherein the dialogue separation unit is configured to provide for the center channel only the dialogue components in a first separate audio signal and the non-dialogue components in a second separate audio signal, and wherein the loudness processing unit is configured to combine the second separate audio channel with the left and right channels for loudness processing,
a multichannel signal comprising a center channel and a plurality of further channels, wherein the dialogue separation unit is configured to provide for the center channel only the dialogue components in a first separate audio signal and the non-dialogue components in a second separate audio signal, and wherein the loudness processing unit is configured to combine the second separate audio signal with the further channels for loudness processing, or
a multichannel signal comprising a center channel, a left channel, a right channel and further channels, wherein the system further comprises a downmixer configured to downmix the center channel, the left channel and the right channel to two channels, wherein the dialogue separation unit is configured to provide for each of the downmixed two channels the dialogue components in a first separate audio signal and the non-dialogue components in a second separate audio signal, and wherein the loudness processing unit is configured to combine the second separate audio signals with the further channels for loudness processing.

37-40. (canceled)

41. The system of claim 22, further comprising a post processing unit configured to further process the processed first separate audio signal and the processed second separate audio signal by applying spatial audio processing and/or specific algorithms before the processed first and second separate audio signals are combined.

42. A non-transitory computer-readable medium having executable instructions stored thereon that, when executed by a processor, performs operations of:
providing the dialogue components of an original audio signal in a first separate audio signal;
providing the non-dialogue components of the original audio signal in a second separate audio signal;
processing the first separate audio signal and the second separate audio signal separately, wherein processing the first and second separate audio signals comprises processing the loudness of the first separate audio signal and/or of the second separate audio signal; and
combining the processed first and second separate audio signals to provide a processed audio signal.

43. The non-transitory computer-readable medium of claim 42, wherein processing the first separate audio signal comprises:
determining a short-term loudness level of the first separate audio signal;
determining whether the determined short-term loudness level is less than a predefined minimum dialogue loudness level DLL_{MIN},
if the determined short-term loudness level is less than the minimum dialogue loudness level DLL_{MIN}, amplify the first separate audio signal towards the predefined minimum dialogue loudness level DLL_{MIN},
if the determined short-term loudness level is not less than the minimum dialogue loudness level DLL_{MIN}, not modify the first separate audio signal.

44. The non-transitory computer-readable medium of claim 43, further performing the operations of:
determining a voice activity in the first separate audio signal;
amplify the first separate audio signal towards the minimum dialogue loudness level DLL_{MIN} only in case a voice activity has been determined.

45. The non-transitory computer-readable medium of claim 44, wherein determining a voice activity comprises determining if the short-term loudness level of the first separate audio signal is higher than a threshold dialogue loudness level DLL_{THRESH}, wherein the first separate audio signal is amplified towards the minimum dialogue loudness level DLL_{MIN} only in case the determined short-term loudness level is higher than the threshold dialogue loudness level DLL_{THRESH}.

46. The non-transitory computer-readable medium of claim 42, wherein processing the second separate audio signal comprises:
determining a short-term loudness level of the first separate audio signal or obtaining a predefined minimum dialogue loudness level DLL_{MIN} of the first separate audio signal;
determining a short-term loudness level of the second separate audio signal;
determining whether the difference between the short-term loudness level of the first separate audio signal and the short-term loudness level of the second separate audio signal or the difference between the minimum dialogue loudness level DLL_{MIN} and the short-term loudness level of the second separate audio signal is less than a predefined minimum dialogue to non-dialogue ratio D2ND_{MIN};
if so, decreasing the loudness level of the second separate audio signal such that said difference approaches the minimum dialogue to non-dialogue ratio D2ND_{MIN},
if not so, not modify the second separate audio signal.
